(19) United States
(12) Patent Application Publication
(10) Pub. No.: US 2026/0182053 A1
(43) Pub. Date: Jun. 25, 2026

(54) METHOD OF MANUFACTURING SEMICONDUCTOR DEVICE

(71) Applicant: CANON KABUSHIKI KAISHA, Tokyo (JP)

(72) Inventors: KOJI HARA, Chiba (JP); ATSUSHI FURUBAYASHI, Kanagawa (JP); AKIRA MATSUZAKI, Kanagawa (JP)

(21) Appl. No.: 19/425,124

(22) Filed: Dec. 18, 2025

(30) Foreign Application Priority Data
Dec. 24, 2024 (JP) 2024-227250

(51) Int. Cl. H10F 39/00; H10F 39/18

(52) U.S. Cl. CPC H10F 39/024; H10F 39/18

(57) ABSTRACT

A method of manufacturing a semiconductor device that includes a substrate having a first surface and a second surface that faces away from the first surface and a plurality of wiring layers. The second surface is disposed between the first surface and the plurality of wiring layers. The method includes preparing the substrate to have an uneven structure including recessed portions and raised portions that are provided on the first surface, and forming the first film with a flat upper surface by applying a precursor onto the substrate such that an amount of the precursor applied onto the recessed portions is greater than the amount of the precursor applied onto other portions.

### BACKGROUND

### Field of the Technology

The present disclosure relates to a method of manufacturing a semiconductor device.

### Description of the Related Art

Japanese Patent Laid-Open No. 2021-002542 discloses a semiconductor device having an uneven structure on the light incident surface of a semiconductor substrate.

### SUMMARY

In the step of manufacturing a semiconductor device having an uneven structure disclosed in Japanese Patent Laid-Open No. 2021-002542, the planarization property of an insulating film after the uneven structure is formed may decrease.

According to an aspect of the present disclosure, there is provided a method of manufacturing a semiconductor device including a substrate having a first surface and a second surface that faces away from the first surface and a plurality of wiring layers, the second surface being disposed between the first surface and the plurality of wiring layers, the method including: preparing the substrate to have an uneven structure including a recessed portion and a raised portion that are provided on the first surface; and forming the first film with a flat upper surface by applying a precursor onto the substrate such that an amount of the precursor applied onto the recessed portion is greater than an amount of the precursor applied onto other portions.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating the structure of a planarization device.

FIGS. 2A, 2B, and 2C are schematic diagrams for describing planarization processing.

FIGS. 3A and 3B are schematic diagrams for describing a method of manufacturing a semiconductor device according to a first embodiment.

FIGS. 4A, 4B, and 4C are schematic diagrams for describing a method of manufacturing the semiconductor device according to the first embodiment.

FIGS. 5A, 5B, and 5C are schematic diagrams for describing driving of the semiconductor device according to the first embodiment.

FIGS. 6A, 6B, and 6C are schematic diagrams for describing a method of manufacturing a semiconductor device according to a modification of the first embodiment.

FIGS. 7A, 7B, 7C, 7D, and 7E are schematic diagrams for describing a method of manufacturing a semiconductor device according to a second embodiment.

FIGS. 8A, 8B, and 8C are schematic diagrams for describing examples of application of a semiconductor device according to a third embodiment.

### DESCRIPTION OF THE EMBODIMENTS

Embodiments will be described with reference to the drawings. It should be noted that the following embodiments do not limit the disclosure according to the claims. A plurality of features is described in the embodiments, but not all of these features are essential to the disclosure, and the plurality of features may be combined arbitrarily. In addition, in the attached drawings, identical reference numbers may be assigned to the identical or similar components to omit redundant descriptions.

The embodiments of the present disclosure will be described in detail below with reference to the drawings. It should be noted that terms indicating specific directions or positions (for example, up, down, right, left, and other terms including these terms) are used as necessary in the following description. These terms are used to facilitate the understanding of embodiments that reference the drawings, and the technical scope of the present disclosure is not limited by the meanings of the terms.

In this specification, plan view refers to view in the direction orthogonal to the upper surface of a semiconductor substrate. In addition, cross-sectional view refers to a plane orthogonal to the upper surface of the semiconductor substrate. It should be noted that, when the upper surface of the semiconductor substrate is rough on a microscopic level, plan view is defined on the basis of the upper surface of the semiconductor substrate on a macroscopic level. It should be noted that the upper surface of the semiconductor substrate is a surface on which an element formed on the semiconductor substrate, such as the gate of a transistor, is provided or a surface on which a connection portion for a contact plug is present.

In addition, expressions, such as “A or B”, “at least one of A and B”, “at least one of A or/and B”, and “one or more of A or/and B” include all possible combinations of the enumerated items unless explicitly defined otherwise. That is, the expressions above are understood to disclose all cases including the case in which at least one A is included, the case in which at least one B is included, and the case in which both at least one A and at least one B are included. This also applies similarly to combinations of three or more elements.

In the following description, the anode of an avalanche photodiode (APD) is set to a fixed potential, and a signal is extracted from the cathode side. Accordingly, the semiconductor region of a first conductivity type that has, as the majority carrier, the electric charge of the same polarity as the signal electric charge is an N-type semiconductor region, and the semiconductor region of a second conductivity type that has, as the majority carrier, the electric charge of the polarity different from that of the signal electric charge is a P-type semiconductor region. It should be noted that, even when the cathode of the APD is set to a fixed potential and a signal is extracted from the anode side, the present disclosure is valid. In this case, the semiconductor region of the first conductivity type that has, as the majority carrier, the electric charge of the same polarity as the signal electric charge is the P-type semiconductor region, and the semiconductor region of the second conductivity type that has, as the majority carrier, the electric charge of the polarity different from that of the signal electric charge is the N-type semiconductor region. The case in which one of the nodes of the APD is set to a fixed potential will be described below, but the potentials of both nodes may vary.

The term “impurity concentration” used in this specification refers to the net impurity concentration obtained by subtracting the portion compensated by the reverse conductive type impurity. That is, the impurity concentration refers to the NET doping concentration. The region in which the P-type doped impurity concentration is higher than the N-type doped impurity concentration is the P-type semiconductor region. Conversely, the region in which the N-type doped impurity concentration is higher than the P-type doped impurity concentration is the N-type semiconductor region.

### First Embodiment

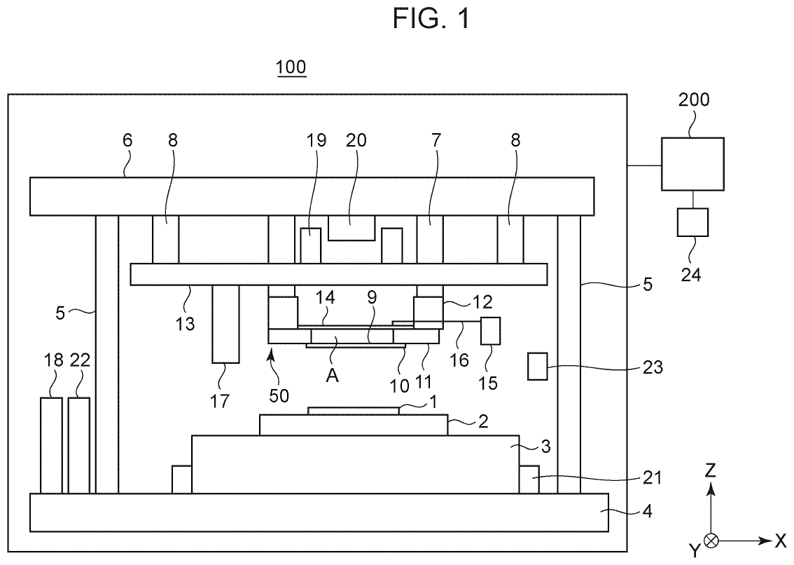

FIG. 1 is a schematic diagram illustrating the structure of a planarization device 100 according to a first embodiment. Directions are indicated in the XYZ coordinate system in which an XY plane is the horizontal plane. Generally, a substrate 1, which is an object to be processed, is placed on a substrate stage 3 such that the surface thereof is parallel to the horizontal plane (XY plane). Accordingly, in the following description, the directions orthogonal to each other within a plane along the surface of the substrate 1 are defined as an X-axis and a Y-axis, and the direction orthogonal to both the X-axis and the Y-axis is defined as a Z-axis. In addition, in the following description, the directions parallel to the X-axis, Y-axis, and Z-axis in the XYZ coordinate system are referred to as an X direction, a Y direction, and a Z direction, respectively, and the rotation directions about the X-axis, the Y-axis, and the Z-axis are referred to as a OX direction, a OY direction, and a OZ direction, respectively. The substrate 1 will be described later, but the substrate 1 is a member to which semiconductor processes are applicable, such as a semiconductor wafer, a semiconductor wafer on which a wiring structure has been formed, a glass substrate on which elements have been formed, or a metal substrate.

The underlying pattern on the substrate has an uneven profile caused by the pattern formed in the previous step, and particularly with the recent multilayer structure of memory elements, some process substrates have the step height of approximately 100 nm. The steps caused by gentle undulation of the entire substrate can be corrected by the focus tracking function of the scan exposure apparatus used in a photolithography step. However, the fine unevenness in a fine pitch that fall within the exposure slit area of the exposure device may fall outside the depth of focus (DOF) of the exposure device. Methods that form a planarization layer or perform planarization, such as spin-on carbon (SOC) and chemical mechanical polishing (CMP), are conventionally used as methods that planarize the underlying pattern of a substrate. However, the conventional technology has a disadvantage in that sufficient planarization performance cannot be obtained. For example, the manufacturing process has evolved to new technology nodes, such as 22 nm, 16 nm, 14 nm, and 10 nm. Even through a practically sufficient planarization layer is obtained in the node one generation before, the planarization layer may not be practical in the next node. For example, the unevenness of the surface of the planarization layer that is permitted at the previous node may not be allowed in the next node. In addition, the CMP has a high process cost and the applicable steps are limited, and the unevenness of the underlying layer due to future multilayering is expected to increase further.

A planarization device that planarizes a substrate by using imprint technology is being considered to solve this disadvantage. The planarization device planarizes a local area or the entire surface of the substrate by bringing a flat surface of a member or a member (flat template) with no pattern into contact with an uncured composition that has been supplied to the substrate in advance. After that, the composition is cured with the composition in contact with the template, and the flat template is separated from the cured composition. As a result, a planarization layer is formed on the substrate. This planarization device is not affected by the unevenness of the pattern surface of the substrate unlike the planarization method that uses SOC sacrificial film, which is generally used, the accuracy of planarization is expected to be improved as compared with existing methods.

The planarization device 100 in FIG. 1 can be realized by a shaping device that shapes a composition on the substrate 1 by using a plate (superstrate) 9, which is a pressing member. The planarization device 100 cures the composition with the material on the substrate 1 in contact with the plate 9 and separates the plate 9 from the cured composition, thereby forming a planarization layer of the material on the substrate 1.

The substrate 1 is a semiconductor, an insulator, or a metal substrate and can have a circular shape like a silicon wafer or a quartz wafer or a rectangular shape like a (mother) glass for a flat panel display (FPD). The material of the substrate 1 can be a single-crystal silicon wafer but is not limited to this. The material of the substrate can be an elemental semiconductor or a compound semiconductor, such as silicon, germanium, diamond, silicon carbide, silicon germanium, gallium nitride, gallium arsenide, indium arsenide, or cadmium telluride. In addition, the material of the substrate 1 can be an inorganic insulator, such as silicon oxide, silicon nitride, aluminum oxide, or aluminum nitride. In addition, the material of the substrate 1 can be an organic insulator, such as polyimide, polyamide, or polycarbonate. In addition, the substrate 1 may be an aluminum, a titanium-tungsten alloy, an aluminum-silicon alloy, or an aluminum-copper-silicon alloy. That is, the substrate 1 can include one or more materials selected arbitrarily from the materials described above. It should be noted that at least one layer including a semiconductor, insulator, or metal film may be formed on the surface of the substrate 1, and the surface can be flat or uneven. In addition, a close contact layer may be formed on the surface of the substrate by a surface treatment, such as silane coupling treatment, silazane treatment, or organic thin film formation, to improve contact with the composition. It should be noted that the substrate 1 typically has a circular shape with a diameter of 300 mm but is not limited to this.

The plate 9 can be made of a light-transmitting material in consideration of a light illumination step. Such a material is, for example, a light-transmitting inorganic material, such as glass or quartz, or a light-transmitting organic material, such as PMMA (polymethyl methacrylate) or polycarbonate resin. The plate 9 may be a rigid plate or a flexible film. In addition, the plate 9 has a flat surface that is in contact with the composition. It should be noted that the plate 9 preferably has a circular shape with a diameter larger than 300 mm and smaller than 500 mm, but the shape is not limited to this. In addition, the thickness of the plate 9 is preferably not less than 0.25 mm and less than 2 mm, but the thickness is not limited to this. It should be noted that, when the material of composition is a thermosetting material rather than a light-curing material, the plate 9 does not need to be transparent and the material only needs to have the characteristics described above.

The composition is a precursor that becomes at least a portion of a planarization film when cured and is a curable composition that can cure upon receiving light or thermal energy. The composition that cures when receiving light or thermal energy can be a photo-curable composition that cures when illuminated with light, a heat-curable composition that cures when heated, or a photo-thermal curable composition that cures when receiving light and thermal energy. A light-curable composition is, for example, a UV-curable liquid. A UV-curable liquid can be typical a monomer, such as an acrylate or a methacrylate. The curable composition may also be referred to as a shapable material. In the following description, a shapable material is simply referred to as a material.

The planarization device 100 includes a substrate chuck 2, a substrate stage 3, a base plate 4, support columns 5, a top plate 6, a guide bar 7, support columns 8, plate chucks 11, heads 12, and an alignment shelf 13, as illustrated in FIG. 1. The planarization device 100 further includes a pressure adjustment unit 15, a supply unit 17, a substrate transport unit 18, an alignment scope 19, a light source 20, a stage drive unit 21, a plate transport unit 22, a cleaning unit 23, an input unit 24, and a control unit 200. The substrate chuck 2 and the substrate stage 3 can hold and move the substrate 1. In addition, the plate chucks 11 and the heads 12 can hold and move the plate 9.

The substrate 1 is carried in from the outside of the planarization device 100 by the substrate transport unit 18 including a transport hand and the like and is held by the substrate chuck 2. The substrate stage 3 is supported by the base plate 4 and is driven in the X direction and the Y direction to locate the substrate 1 held by the substrate chuck 2 at a predetermined position. The stage driving unit 21 includes, for example, a linear motor or an air cylinder and drives the substrate stage 3 at least in the X direction and the Y direction, but the stage driving unit 21 may also have the function of driving the substrate stage 3 in the directions of two or more axes (for example, in the directions of six axes). In addition, the stage driving unit 21 includes a rotation mechanism and can rotationally drive the substrate chuck 2 or the substrate stage 3 in the OZ direction.

The plate 9, which is a pressing member, is carried in from the outside of the planarization device 100 by the transport unit 22 including a transport hand and the like and is held by the plate chucks 11. The plate 9 has, for example, a circular or rectangular outer shape and has a flat surface 10 in contact with a material disposed on the substrate 1 and a second surface on the opposite side of the first surface. In the embodiment, the size of the flat surface 10 is the same as or larger than that of the substrate 1. The plate chucks 11 are supported by the heads 12 and have the function of correcting the position of the plate 9 in the OZ direction (the inclination about the Z-axis). The plate chuck 11 and the head 12 each include an opening through which light (ultraviolet light) emitted from the light source 20 via a collimator lens passes. The plate chucks 11 functions as holding portions that mechanically hold the plate 9. For example, the plate chucks 11 attract the second surface of the plate 9 with the second surface facing upward and hold the plate 9. In addition, the heads 12 mechanically hold the plate chucks 11. The plate chucks 11 and the heads 12 constitute a forming unit 50 that performs the formation step of the planarization film. The heads 12 constitute a driving mechanism (not illustrated) for positioning the spacing between the substrate 1 and the plate 9 when the plate 9 is brought into contact with and is separated from a material on the substrate 1, and the head 12 moves the plate 9 in the Z direction. The drive mechanism of the heads 12 can include an actuator, such as a linear motor, an air cylinder, or a voice coil motor. In addition, a load cell for measuring a pressing force (pushing force) of the plate 9 against the material on the substrate can be disposed on the plate chuck 11 or the head 12. The plate deformation mechanism (plate deformation portion) first includes a sealing member 14 that has, as a sealed space, a space region A formed by a space present inside the plate chucks 11 and an internal space surrounded by the plate 9. The plate deformation mechanism further includes the pressure adjustment unit 15, installed outside the plate chucks 11, that adjusts the pressure in the space region A. The sealing member 14 is formed of a light-transmissive flat plate member, such as quartz glass, and partially has a connection port (not illustrated) for a pipe 16 connected to the pressure adjustment unit 15. The pressure adjustment unit 15 can increase the amount of convex deformation of the plate 9 toward the substrate by increasing the pressure of the space region A. In addition, the pressure adjustment unit 15 can reduce the amount of convex deformation of the plate 9 by reducing the pressure of the space region A. The support columns 5 that support the top plate 6 is disposed on the base plate 4. The guide bars 7 are suspended from the top plate 6, pass through the alignment shelf 13, and are fixed to the heads 12. The alignment shelf 13 is suspended from the top plate 6 via the support columns 8. The guide bars 7 pass through the alignment shelf 13. In addition, a height measurement system (not illustrated) for measuring the height (flatness) of the substrate 1 held by the substrate chuck 2 by, for example, using an oblique incidence image shift method is disposed on the alignment shelf 13.

The alignment scope 19 includes an optical system and an imaging system for observing a reference mark provided on the substrate stage 3 and an alignment mark provided on the plate 9. However, when no alignment mark is provided on the plate 9, the alignment scope 19 may be absent. The alignment scope 19 is used for alignment that measures the relative position between the reference mark provided on the substrate stage 3 and the alignment mark provided on the plate 9 and corrects the positional deviation.

The supply unit 17 includes a dispenser that contains a discharge port (nozzle) through which an uncured material is ejected onto the substrate 1 and supplies (applies) the material onto the substrate. The supply unit 17 adopts, for example, a piezojet method or a micro solenoid method and can supply a minute volume (approximately 1 picoliter) of material onto the substrate 1 that is being scan-driven by the substrate stage 3. It should be noted that the number of discharge ports in the supply unit 17 is not limited and may be one (a single nozzle) or more than one (for example, 100 or more). A plurality of nozzles may constitute a linear nozzle array including one row or a plurality of rows. In particular, a dispenser that uses a system known as an inkjet head is preferable because liquid material is applicable to the substrate as fine droplets. In particular, a piezo inkjet head including at least one discharge energy generating body for piezoelectric elements for each discharge port is more preferable because the volume of droplets to be discharged can be changed.

The cleaning unit 23 cleans the plate 9 with the plate 9 held by the plate chucks 11. In the embodiment, the cleaning unit 23 removes the material attached to the plate 9, particularly to the flat surface 10, by separating the plate 9 from the cured material on the substrate. The cleaning unit 23 may, for example, wipe off the material attached to the plate 9 or remove the material attached to the plate 9 by using UV irradiation, static electricity removal, wet cleaning, and dry plasma cleaning, or the like.

The control unit 200 is configured by a computer device including a CPU and a memory and controls the entire planarization device 100. The control unit 200 functions as a processing unit that comprehensively controls individual units of the planarization device 100 and performs planarization processing. Here, the planarization processing refers to processing that planarizes the material by conforming the flat surface 10 of the plate 9 to the surface shape of the substrate 1 with the flat surface 10 in contact with the material on the substrate. It should be noted that the planarization processing is generally performed in units of lots, that is, the planarization processing is performed on a plurality of substrates included in the same lot.

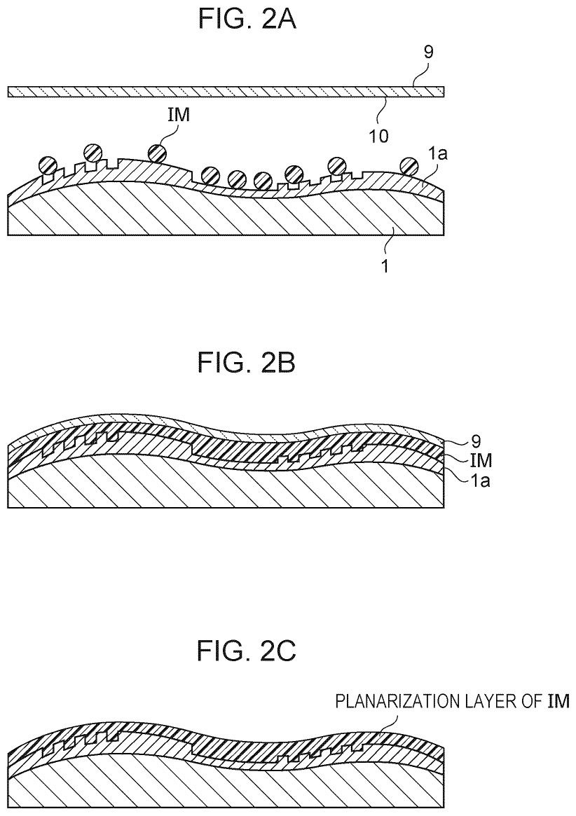

Next, the planarization processing will be described with reference to FIGS. 2A, 2B, and 2C. First, the supply unit 17 supplies a material IM to the substrate 1 on which an underlying pattern 1a has been formed. FIG. 2A illustrates the state in which the plate 9 is not yet in contact with the material IM after the material IM is disposed on the substrate 1. Next, as illustrated in FIG. 2B, the material IM on the substrate 1 is brought into contact with the flat surface 10 of the plate 9. The material IM spreads across the entire surface of the substrate 1 by being pressed by the plate 9. FIG. 2B illustrates the state in which the entire flat surface 10 of the plate 9 is in contact with the material IM on the substrate 1, and the flat surface 10 of the plate 9 has conformed to the surface shape of the substrate 1. Then, in the state illustrated in FIG. 2B, the material IM on the substrate 1 is illuminated with light from the light source 20 through the plate 9, and accordingly, the material IM is cured. After that, the plate 9 is separated from the cured material IM on the substrate 1. As a result, a layer of the material IM (planarization layer) with a uniform thickness is formed on the entire surface of the substrate 1. FIG. 2C illustrates the state in which the planarization layer made of the material IM has been formed on the substrate 1. In the following description, contact (close contact) or separation between the flat surface 10 of the plate 9 and the material IM on the substrate 1 is simply expressed as contact (close contact) or separation of the plate 9 and the material IM on the substrate 1. In addition, in the following description, the material IM that has been supplied to the substrate 1 is also referred to as a precursor, and the material IM after being cured is also referred to as a film.

Next, a method of manufacturing an article (semiconductor device, liquid crystal display device, color filter, MEMS, or the like) including this planarization device 100 will be described. The manufacturing method includes the step of planarizing the composition disposed on the substrate (wafer, glass substrate, or the like) by bringing the composition into contact with a mold using the planarization device described above, the step of curing the composition, and the step of separating the composition from the mold. As a result, the planarization film is formed on the substrate. After that, processing such as patterning processing by using a lithography device is performed on the substrate on which the planarization film has been formed, the substrate subjected to patterning processing is processed by other known processing steps, and accordingly, an article is manufactured. The other known steps include etching, resist stripping, dicing, bonding, and packaging, and the like. According to this manufacturing method, articles of higher quality than before can be manufactured.

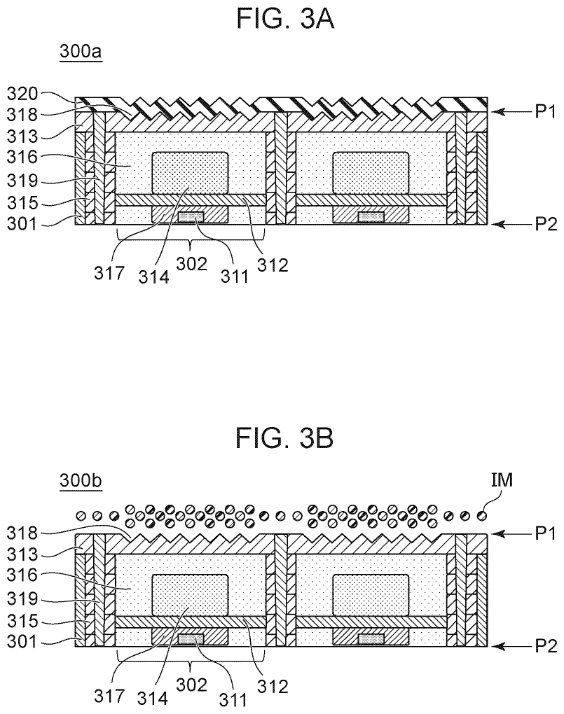

The case of a semiconductor device as a specific example will be described below. The semiconductor device is assumed to be, for example, a photoelectric conversion sensor. FIGS. 3A and 3B are schematic diagrams for describing the method of manufacturing the semiconductor device according to the embodiment.

A semiconductor device 300a and a semiconductor device 300b each include a semiconductor substrate 301, and the semiconductor substrate 301 includes a photoelectric conversion unit 302. The photoelectric conversion unit 302 generates an electric charge that depends on incident light. In addition, a first surface P1 is the upper surface (light incident surface) of the semiconductor substrate 301, and a second surface P2 is the lower surface of the semiconductor substrate 301 that faces away from the first surface P1. The semiconductor devices 300a and 300b are back-illuminated semiconductor devices each including a plurality of wiring layers (not illustrated) on a second surface P2 side.

The semiconductor substrate 301 further includes a first semiconductor region 311, a second semiconductor region 312, a third semiconductor region 313, a fourth semiconductor region 314, a fifth semiconductor region 315, a sixth semiconductor region 316, and a seventh semiconductor region 317. The first semiconductor region 311 is disposed at a first depth with respect to the second surface P2, the second semiconductor region 312 is disposed at a second depth with respect to the second surface P2, and the third semiconductor region 313 is disposed at a third depth with respect to the second surface P2.

Here, the second depth with respect to the second surface P2 is deeper than the first depth, and the third depth with respect to the second surface P2 is deeper than the second depth. It should be noted that, in the embodiment, of electron-hole pairs generated by the photoelectric conversion unit 302 through incident light, the case in which electrons are used as signal electric charge will be described.

When electrons are used as signal electric charge, the first semiconductor region 311, the fourth semiconductor region 314, the sixth semiconductor region 316, and the seventh semiconductor region 317 are configured as N-type semiconductor regions. In addition, when electrons are used as signal electric charge, the second semiconductor region 312, the third semiconductor region 313, and the fifth semiconductor region 315 are configured as P-type semiconductor regions. However, signal electric charge is not limited to electrons, and holes may also be used as signal electric charge. When holes are used as signal electric charge, the conductivity types of the semiconductor regions described above are different.

In the embodiment, the first semiconductor region 311 is disposed near the second surface P2, and the seventh semiconductor region 317 is disposed therearound. The second semiconductor region 312 is disposed in a position that overlaps the first semiconductor region 311 and the seventh semiconductor region 317 in plan view. In addition, the fourth semiconductor region 314 is disposed at a position that overlaps the second semiconductor region 312 in plan view, and the sixth semiconductor region 316 is disposed therearound.

A contact portion, which is not illustrated, formed of a metal is connected to the first semiconductor region 311. This contact portion supplies a voltage VH to the first semiconductor region 311 (anode). This voltage VH is, for example, +1 V. In addition, a contact portion, which is not illustrated, formed of a metal is connected to the fifth semiconductor region 315. This contact portion supplies a voltage VL to the fifth semiconductor region (cathode). This voltage VL is, for example, −30 V.

As described above, a reverse bias voltage is supplied to the anode and the cathode of the photoelectric conversion unit 302 such that the photoelectric conversion unit 302 performs avalanche multiplication operation. When such a voltage is supplied, the electric charge generated by incident light causes avalanche multiplication, and avalanche current is generated.

It should be noted that, when a reverse bias voltage is supplied, there are a Geiger mode that operates when the difference in potential between the anode and the cathode is greater than a breakdown voltage and a linear mode that operates when the difference in potential between the anode and the cathode is near or below the breakdown voltage.

An avalanche photodiode (APD) that operates in the Geiger mode is referred to as a single-photon avalanche diode (SPAD). The photoelectric conversion unit 302 may operate in the linear mode or in the Geiger mode. Since the difference in potential in the case of a SPAD becomes larger than an APD in the linear mode and the breakdown voltage more pronounced, a SPAD is preferable.

The first semiconductor region 311 has a higher N-type impurity concentration than the fourth semiconductor region 314 and the seventh semiconductor region 317. A PN junction is formed between the P-type second semiconductor region 312 and the N-type first semiconductor region 311, but the entire second semiconductor region 312 become a depletion layer region by making the impurity concentration of the second semiconductor region 312 lower than that of the first semiconductor region 311. In addition, this depletion layer extends to a portion of the first semiconductor region 311, and a strong electric field is induced in the extended depletion layer. This strong electric field causes avalanche multiplication in the depletion layer that has extended to a portion of the first semiconductor region 311, and the current based on the amplified electric charge is output as a signal electric charge. When the light incident on the semiconductor substrate 301 is photoelectrically converted, and avalanche multiplication occurs in the depletion layer region (avalanche multiplication region), the generated electric charge of the first conductivity type is collected in the first semiconductor region 311.

It should be noted that the fourth semiconductor region 314 and the seventh semiconductor region 317 are formed to have similar sizes in FIGS. 3A and 3B, but the sizes of these semiconductor regions are not limited to this. For example, the fourth semiconductor region 314 may be formed larger than the seventh semiconductor region 317 such that electric charge from a wider area can be collected into the first semiconductor region 311.

An uneven structure 318 formed by groove portions of trenches is disposed on the first surface P1. The uneven structure 318 is surrounded by the third semiconductor region 313 and scatters light incident on the first surface P1. Since the incident light advances diagonally within the semiconductor substrate 301, a light path length greater than or equal to the thickness of the semiconductor substrate 301 can be obtained, and photoelectric conversion of light with a longer wavelength can be performed as compared with the case the uneven structure 318 is not provided. In addition, since the uneven structure 318 prevents the reflection of the incident light within the semiconductor substrate 301, the effect of improving the photoelectric conversion efficiency of the incident light can be obtained.

It should be noted that, in this specification, the uneven structure 318 includes a form in which raised portions of the uneven structure 318 project beyond the first surface P1, but the uneven structure 318 is not limited to this form. A plane parallel to the first surface P1 at the depth position that bisects the height difference between the lowest portion and the highest portion of the uneven structure 318 is defined as a reference plane. In the uneven structure 318, deeper portions than this reference surface are referred to as recessed portions and shallower portions than this reference surface are referred to as raised portions.

The fourth semiconductor region 314 and the uneven structure 318 are disposed so as to overlap each other in plan view. The area of a portion in which the fourth semiconductor region 314 overlaps the uneven structure 318 in plan view is larger than the area of a portion in which the fourth semiconductor region 314 does not overlap the uneven structure 318. The electric charge generated at a position far from the avalanche multiplication region formed between the first semiconductor region 311 and the fourth semiconductor region 314 has a longer travel time to reach the avalanche multiplication region than the electric charge generated at a position close to the avalanche multiplication region. Accordingly, a timing jitter may degrade. When the fourth semiconductor region 314 and the uneven structure 318 are disposed at positions that overlap each other in plan view, since the electric field in a deep portion of the photodiode can be enhanced, and the collection time of electric charge generated at a position far from the avalanche multiplication region can be shortened, a timing jitter can be reduced.

In addition, when the third semiconductor region 313 covers the uneven structure 318 in a three-dimensional manner, thermal excitation electric charge can be suppressed from being generated at the interface portion of the uneven structure. As a result, the dark count rate (DCR) of the photoelectric conversion unit 302 is suppressed.

A separating portion 319 of a trench structure separates adjacent photoelectric conversion units 302, and the P-type fifth semiconductor region 315 formed in the surrounding area separates the adjacent photoelectric conversion units 302 by a potential barrier. It should be noted that, since the plurality of photoelectric conversion units 302 is also separated by the potential of the fifth semiconductor region 315, a trench structure such as the separating portion 319 is not necessary. In addition, the depth and the position of the separating portion 319 to be provided are not limited to the structure illustrated in FIG. 3A. The separating portion 319 may be a deep trench isolation (DTI) that passes through the semiconductor substrate 301 or a DTI that does not pass through the semiconductor substrate 301. The light-shielding performance may be improved by a metal being embedded in the DTI. The separating portion 319 may surround the entire perimeter of the photoelectric conversion unit 302 in plan view or may be formed only at the opposing side portions of the photoelectric conversion unit 302.

The distance between the separating portions 319 disposed at the closest positions can also be regarded as the size of one photoelectric conversion unit 302. When the size of one photoelectric conversion unit 302 is assumed to be L, distance d from the light incident surface to the avalanche multiplication region satisfies L√2/4<d<L×√2. When the size and the depth of the photoelectric conversion unit 302 satisfy this relational expression, the strength of the electric field in the depth direction near the first semiconductor region 311 is nearly equal to the strength of the electric field in the planar direction. Since the variation in the time required to collect electric charge can be suppressed, generation of a timing jitter can be reduced.

FIG. 3A illustrates the state in which the insulating film 320 has been formed after the uneven structure 318 has been formed on the semiconductor substrate 301. The insulating film 320 is formed to cover the uneven structure 318.

Here, uneven portions can be generated on the upper surface of the insulating film 320 in accordance with the uneven structure 318. When the planarization property of the upper surface of the insulating film 320 is low as described above, for example, a filter layer or a microlens disposed on the insulating film 320 does not exhibit desired performance in some cases. It should be noted that various optical filters, such as a color filter, an infrared cut filter, and a monochrome filter can be used as the filter layer. An RGB color filter for R (red), G (green), and B (blue) or an RGBW color filter further including W pixels can be used. It should be noted that an insulating layer can be provided instead of a color filter for W pixels.

Accordingly, in the embodiment of the present disclosure, as illustrated in FIG. 3B, the amount applied is predetermined such that a more liquid precursor (material IM) is applied onto the recessed portions of the uneven structure 318 and a less liquid precursor is applied onto the other portions. Then, the liquid is cured while the flat surface of the plate is pressed against the liquid as necessary.

An uncured material is applied by using an inkjet head having a piezo element as a discharge actuator mounted on the uneven structure 318 formed in advance. Specifically, this is achieved by striking droplets onto the recessed portions N+1 times or more (where N is a natural number) per unit area and striking droplets onto the first surface P1 N times per unit area. The number of droplets applied as described above can be determined in accordance with the formation pattern of the uneven structure 318. Specifically, in accordance with a drawing map for determining the number (or the amount) of droplets to be applied onto the substrate and the application positions on the upper surface on the basis of the pattern data of a resist mask for forming the uneven structure 318, droplets are applied while the relative position between the discharge port and the substrate is changed. In addition, of the raised portions and the recessed portions included in the uneven structure 318, more droplets can also be applied onto the recessed portions than onto the raised portions by the inkjet head being controlled. In addition, more droplets can also be applied onto the raised portions than onto the first surface P1 by the inkjet head being controlled.

Since the uneven structure 318 is filled as described above, the surface of a first film 321 to be formed subsequently becomes flat. Here, the liquid used here is preferably a composition (a precursor of the cured film) that is cured upon receiving light energy.

For example, an exposure device is used for curing. An ArF liquid immersion exposure apparatus, an ArF dry exposure apparatus, or a KrF exposure apparatus may also be used. The exposure amount can also be adjusted in accordance with the pattern of the uneven structure 318.

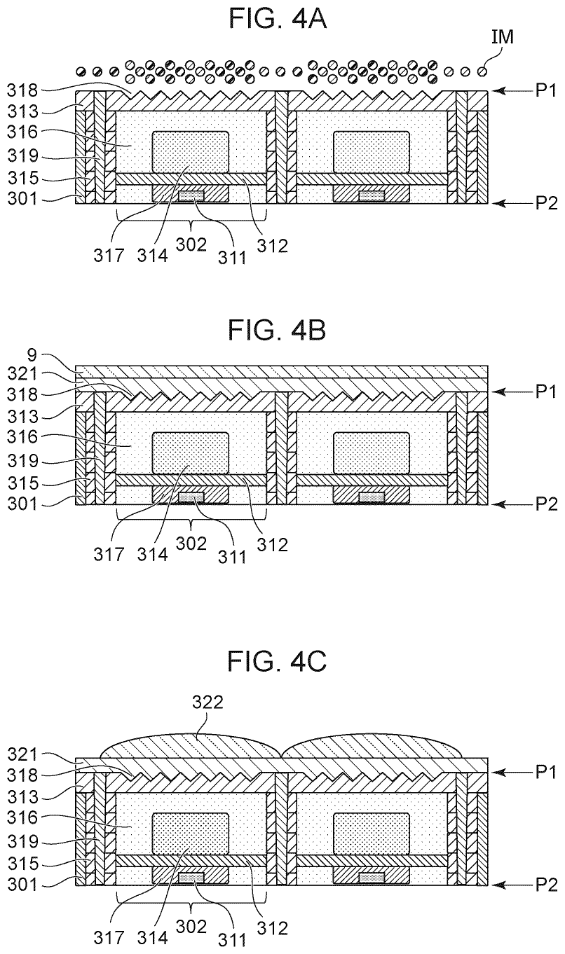

Next, a method of manufacturing the semiconductor device according to the embodiment will be described. FIGS. 4A, 4B, and 4C are schematic diagrams for describing the method of manufacturing the semiconductor device according to the first embodiment. In the manufacturing method illustrated in FIGS. 4A, 4B, and 4C, the planarization method described in FIGS. 1, 2A, 2B, and 2C has been applied to the method of manufacturing the semiconductor device described in FIG. 3B.

In FIG. 4A, after the step of preparing the semiconductor substrate 301 on which the uneven structure 318 has been formed, the material IM of a cured film is applied, as in FIG. 3B. The amount of the material IM applied is adjusted along the shape of the upper surface of the semiconductor substrate 301. Here, the material IM is supplied such that the amount applied onto the recessed portions of the uneven structure 318 is greater than that onto the flat upper surface of the semiconductor substrate 301 therearound. The amount applied can be controlled, for example, by changing the number of droplets or the size of droplets of the precursor (liquid) of the material IM discharged by an inkjet method.

Next, as illustrated in FIG. 4B, the plate 9 is brought into contact with the material IM as necessary, and the upper surface of the material IM is planarized. Then, the material IM is illuminated with light through the plate 9. The material IM is cured due to the illumination of light. After that, the plate 9 is separated from the cured material IM on the semiconductor substrate 301. This planarization processing forms the first film 321 having the upper surface with a high planarization property. Here, the material IM can be, for example, a precursor of an energy-curable resin or the precursor of spin-on carbon (SOC).

As illustrated in FIG. 4C, a microlens 322 is formed on the upper surface of the first film 321. Since the microlens 322 is formed on the first film 321 with a high planarization property, desired performance can be easily achieved. It should be noted that the filter layer may be formed on the upper surface of the first film 321 before the microlens 322 is formed. In this case, since the filter layer is formed on the first film 321 with a high planarization property, desired performance can be easily achieved.

As described above, the method of manufacturing the semiconductor device according to the embodiment can improve the planarization property of the top portion of the uneven structure.

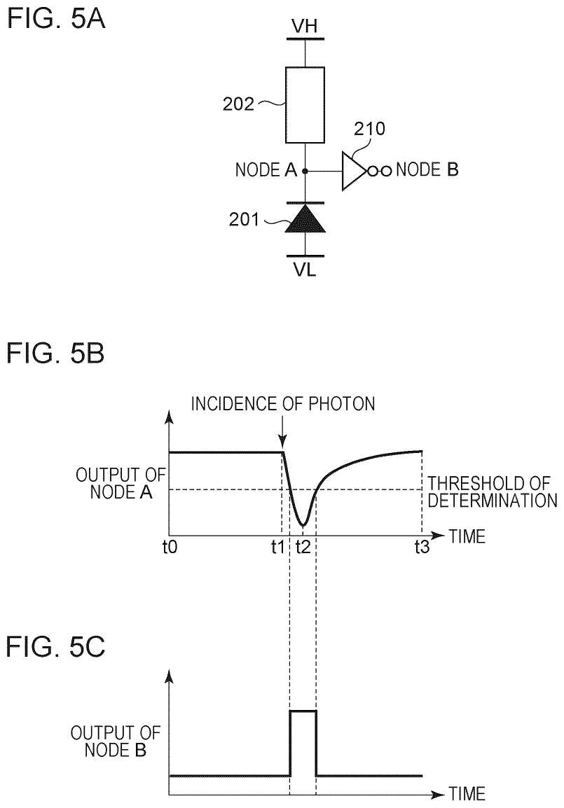

It should be noted that the FIGS. 5A, 5B, and 5C are diagrams schematically illustrating the relationship between the operation of the APD and output signals.

FIG. 5A illustrates an APD 201, a quenching element 202, and a waveform shaping unit 210. Here, the input side of the waveform shaping unit 210 is referred to as node A, and the output side is referred to as node B. FIG. 5B illustrates changes in the waveform of node A in FIG. 5A, and FIG. 5C illustrates changes in the waveform of node B in FIG. 5A.

A potential difference of (VH−VL) is applied to the APD 201 in FIG. 5A between time to and time t1. When a photon is incident on the APD 201 at time t1, avalanche multiplication occurs in the APD 201, avalanche multiplication current flows through the quenching element 202, and the voltage of node A drops. When the amount of voltage drop further increases and the potential difference applied to the APD 201 decreases, the avalanche multiplication of the APD 201 stops as at time t2, and the voltage level of node A does not drop below a certain value. After that, the current that compensates the voltage drop from the voltage VL flows through node A between time t2 and time t3, and the potential level of node A stays at the original potential level at time t3. At this time, the portion of the output waveform of node A that exceeds a certain threshold is shaped by the waveform shaping unit 210 and the shaped waveform is output as a signal from node B.

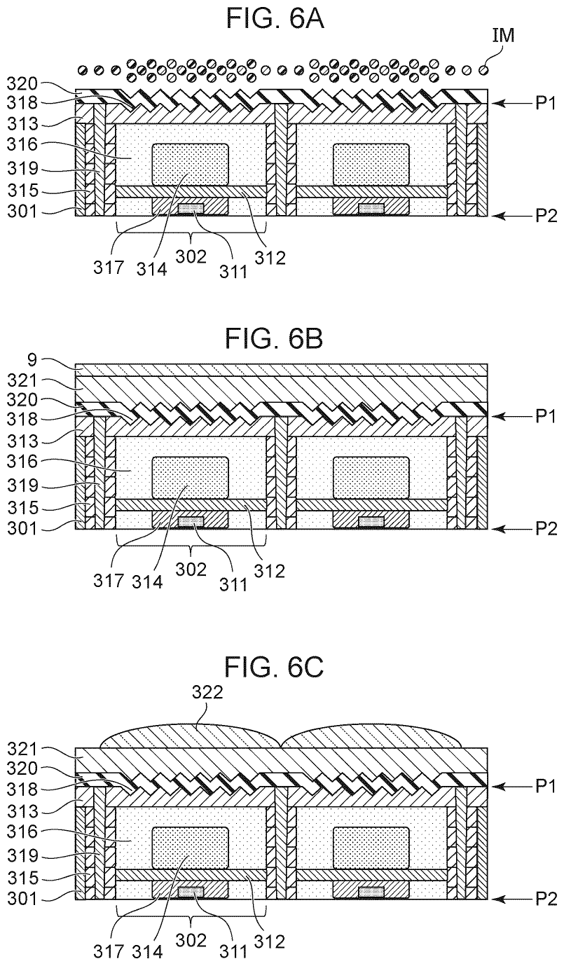

A method of manufacturing a semiconductor device according to a modification of the first embodiment of the present disclosure will be described with reference to FIGS. 6A, 6B, and 6C. In the manufacturing method illustrated in FIGS. 6A, 6B, and 6C, the planarization method described in FIGS. 1, 2A, 2B, and 2C has been applied to the method of manufacturing the semiconductor device described in FIG. 3A. The components and the steps similar to those in FIGS. 4A, 4B, and 4C will not be described in detail below.

In FIG. 6A, after the step of forming the insulating film 320 on the uneven structure 318, the material IM of the cured film is applied, as in FIG. 3A. The amount of the material IM applied is adjusted along the shape of the upper surface of the insulating film 320. Here, the material IM is supplied such that the amount applied onto the recessed portions of the uneven structure 318 is greater than that onto the flat upper surface of the insulating film 320 therearound. The amount applied can be controlled, for example, by changing the number of droplets or the size droplets of the precursor (liquid) of the material IM discharged by an inkjet method.

Next, as illustrated in FIG. 6B, the plate 9 is brought into contact with the material IM as necessary, and the upper surface of the material IM is planarized. Then, the material IM is illuminated with light through the plate 9. The material IM is cured due to the illumination of light. After that, the plate 9 is separated from the cured material IM on the insulating film 320. This planarization processing forms the first film 321 having the upper surface with a high planarization property. Here, the material IM can be, for example, a precursor of an energy-curable resin or a precursor of spin-on carbon (SOC).

As illustrated in FIG. 4C, the microlens 322 is formed on the upper surface of the first film 321. Since the microlens 322 is formed on the first film 321 with a high planarization property, desired performance can be easily achieved. It should be noted that the filter layer may be formed on the upper surface of the first film 321 before the microlens 322 is formed. In this case, since the filter layer is formed on the first film 321 with a high planarization property, desired performance can be easily achieved.

As described above, the method of manufacturing the semiconductor device according to the modification can improve the planarization property of the top portion of the uneven structure.

In the embodiment, when the material IM is applied, more droplets are discharged onto the recessed portions of the uneven structure 318 than onto the other portions by the inkjet head being controlled. However, the present disclosure is not limited to this form. For example, when the material IM is applied, droplets are uniformly applied to the uneven structure 318 and the portions other than the portion in which the uneven structure 318 is provided. After that, the flat plate 9 is brought into contact with the material IM. This method can also make the amount of the material IM located on the recessed portions of the uneven structure 318 greater than the amount of the material IM located on the portions other than the recessed portions of the uneven structure 318. Such a method is also included in the step of applying the precursor such that the amount applied onto the recessed portions is greater than that on the other portions.

### Second Embodiment

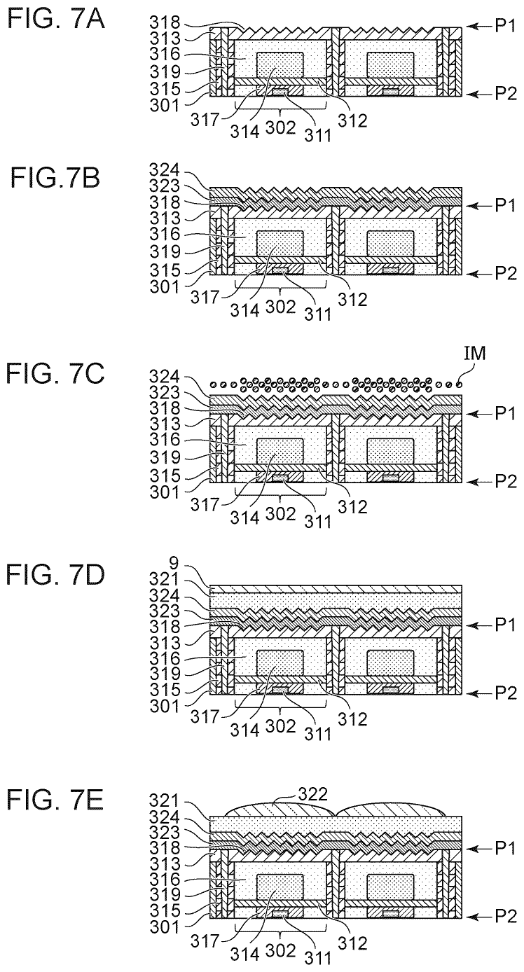

A method of manufacturing a semiconductor device according to a second embodiment will be described. The semiconductor device is assumed to be, for example, a photoelectric conversion sensor. FIGS. 7A, 7B, 7C, 7D, and 7E are schematic diagrams illustrating a method of manufacturing a semiconductor device according to the second embodiment. In the manufacturing method illustrated in FIGS. 7A, 7B, 7C, 7D, and 7E, the first film 321 is formed after a fixed charge film 323 and an anti-reflection film 324 are formed on the uneven structure 318 in the manufacturing method illustrated in FIGS. 4A, 4B, and 4C. The components and the steps similar to those in FIGS. 4A, 4B, 4C, 6A, 6B, and 6C will not be described in detail below.

As illustrated in FIG. 7A, the uneven structure 318 is formed on the semiconductor substrate 301.

In FIG. 7B, after the step of forming the uneven structure 318, the fixed charge film 323 is formed on the semiconductor substrate 301, and the anti-reflection film 324 is formed on the fixed charge film 323. It should be noted that a portion of the fixed charge film 323 formed on the uneven structure 318 has an uneven shape, and a portion of the anti-reflection film 324 formed on the uneven structure 318 has an uneven shape. It should be noted that both the fixed charge film 323 and the anti-reflection film 324 may be formed, or only one of the fixed charge film 323 and the anti-reflection film 324 may be formed.

The refractive index of the anti-reflection film 324 is smaller than the effective refractive index of the uneven structure 318. Here, the effective refractive index refers to the substantial refractive index of the entire uneven structure 318 including the substrate having trenches and the material that fills the trenches. The anti-reflection film 324 is made of, for example, Ta₂O₅. The anti-reflection film 324 can prevent avalanche emission light from being reflected by the back surface of the semiconductor layer and reduce crosstalk caused by avalanche emission light.

In FIG. 7C, the material IM of the cured film is applied after the step in FIG. 7B. The amount of the material IM applied is adjusted along the shape of the upper surface of the fixed charge film 323 or the anti-reflection film 324.

Here, the material IM is supplied such that the amount applied onto the recessed portions of the uneven structure 318 is greater than that onto the flat upper surface of the fixed charge film 323 or the anti-reflection film 324 therearound. The amount applied can be controlled, for example, by changing the number of droplets or the size of droplets of the precursor (liquid) of the material IM discharged by an inkjet method.

Next, as illustrated in FIG. 7D, the plate 9 is brought into contact with the material IM as necessary, and the upper surface of the material IM is planarized. Then, the material IM is illuminated with light through the plate 9. The material IM is cured due to the illumination of light. After that, the plate 9 is separated from the cured material IM on the fixed charge film 323 or the anti-reflection film 324. This planarization processing forms the first film 321 having the upper surface with a high planarization property. Here, the material IM can be, for example, a precursor of an energy-curable resin or a precursor of spin-on carbon (SOC).

As illustrated in FIG. 7E, the microlens 322 is formed on the upper surface of the first film 321. Since the microlens 322 is formed on the first film 321 with a high planarization property, desired performance can be easily achieved. It should be noted that the filter layer may be formed on the upper surface of the first film 321 before the microlens 322 is formed. In this case, since the filter layer is formed on the first film 321 with a high planarization property, desired performance can be easily achieved.

As described above, the method of manufacturing the semiconductor device according to the embodiment can improve the planarization property of the top portion of the uneven structure.

### Third Embodiment

In a third embodiment, examples of applications of the semiconductor devices manufactured by the manufacturing methods according to the first embodiment and the second embodiment will be described. The semiconductor device 910 is assumed to be, for example, a photoelectric conversion sensor.

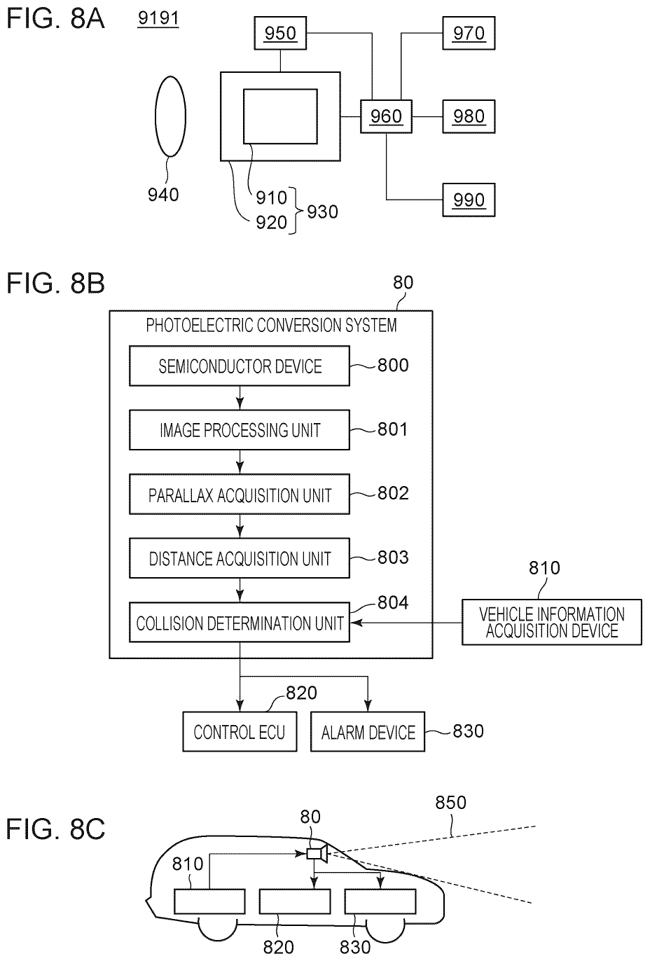

FIG. 8A is a schematic diagram for describing a device 9191 that is an example of application. The device 9191 includes a semiconductor unit 930. The semiconductor unit 930 includes the semiconductor device 910 and a package 920 in which the semiconductor device 910 is housed. The semiconductor device 910 can be manufactured by a manufacturing method according to another embodiment. The package 920 can include a base body to which the semiconductor device 910 is fixed, and a lid body, made of glass or the like, that faces the semiconductor device 910. The package 920 can further include bonding members, such as bonding wires or bumps that connect terminals provided in the base body and terminals provided in the semiconductor device 910 to each other.

The device 9191 can include at least one of an optical device 940, a control device 950, a processing device 960, a display device 970, a storage device 980, and a mechanical device 990. The optical device 940 corresponds to the semiconductor unit 930. The optical device 940 is, for example, a lens, a shutter, or a mirror and includes an optical system that guides light to the semiconductor unit 930. The control device 950 controls the semiconductor unit 930. The control device 950 is a semiconductor unit, such as, for example, an ASIC.

The processing device 960 processes a signal output from the semiconductor unit 930. The processing device 960 is a semiconductor unit, such as a CPU or an ASIC, that constitutes an analog front end (AFE) or a digital front end (DFE). The display device 970 is an EL display device or a liquid crystal display device that displays the information (image) obtained by the semiconductor unit 930. The storage device 980 is a magnetic device or a semiconductor device that stores the information (image) obtained by the semiconductor unit 930. The storage device 980 is a volatile memory, such as a SRAM or a DRAM, or a non-volatile memory, such as a flash memory or a hard disk drive.

The mechanical device 990 includes a movable unit or a driver unit, such as a motor or an engine. The device 9191 displays the signal output from the semiconductor unit 930 on the display device 970 or externally transmits the signal by using a communication device (not illustrated) included in the device 9191. For this reason, the device 9191 preferably further includes the storage device 980 and the processing device 960 in addition to a storage circuit and an arithmetic circuit of the semiconductor unit 930. The mechanical device 990 may be controlled in accordance with a signal output from the semiconductor unit 930.

In addition, the device 9191 is suitable for electronic devices, such as information terminals (for example, smartphones or wearable devices) with imaging functions, cameras (for example, interchangeable lens cameras, compact cameras, video cameras, or surveillance cameras). The mechanical device 990 in such a camera can drive components of the optical device 940 for zooming, focusing, and shutter operation. Alternatively, the mechanical device 990 in the camera can move the semiconductor unit 930 for suppression of vibration.

In addition, the device 9191 can be a transport device, such as a vehicle, a ship, or an aircraft. The mechanical device 990 in the transport device can be used as a moving device. The device 9191 as a transport device is suitable for transporting the semiconductor unit 930 and for assisting and/or automating operation (control) by using imaging functions. The processing device 960 for assisting and/or automating operation (control) can perform processing to operate the mechanical device 990 as a moving device in accordance with the information obtained by the semiconductor unit 930. Alternatively, the device 9191 may be a medical device, such as an endoscope, a measuring device, such as a distance sensor, an analytical device like an electron microscope, a business device, such as a copier, or an industrial device, such as a robot.

In the embodiment described above, good pixel characteristics can be obtained. Accordingly, the value of the semiconductor unit can be enhanced. The enhancement of the value referred to above includes at least one of addition of functions, improvement of performance, improvement of characteristics, increase in reliability, improvement of manufacturing yield, reduction in environmental impact, cost reduction, miniaturization, and weight reduction.

Accordingly, the value of the device 9191 can also be improved by using the semiconductor unit 930 according to the embodiment in the device 9191. For example, when the semiconductor unit 930 is installed in a transport device, excellent performance can be achieved to image the outside of the transport device or measure the external environment of the transport device. Accordingly, in manufacturing and sales of the transport device, installation of the semiconductor unit according to the embodiment in the transport device is advantageous for enhancing the performance of the transport device itself. In particular, the semiconductor unit 930 is suitable for the transport device that assists and/or automates the operation of the transport device by using the information obtained by the semiconductor unit.

Next, a movable body as another example of application will be described. FIG. 8B illustrates an example of a photoelectric conversion system that relates to an on-vehicle camera. The photoelectric conversion system 80 includes a semiconductor device 800. The semiconductor device 800 is, for example, a photoelectric conversion device (imaging device). The photoelectric conversion system 80 includes an image processing unit 801 that performs image processing on a plurality of pieces of image data obtained by the semiconductor device 800 and a parallax acquisition unit 802 that calculates parallax (phase difference of a parallax image) from a plurality of pieces of image data obtained by the photoelectric conversion system 80.

Here, the photoelectric conversion system 80 may include an optical system, which is not illustrated, that guides light to the semiconductor device 800, such as, for example, a lens, a shutter, or a mirror. In addition, a plurality of photoelectric conversion units that are almost conjugate to the pupil of the optical system may be disposed in the pixels of the semiconductor device 800. For example, the plurality of photoelectric conversion units that are almost conjugate to the pupil is disposed to correspond to one microlens. The plurality of photoelectric conversion units receives light beams that have passed through different positions on the pupil of the optical system, and accordingly, the semiconductor device 800 outputs image data corresponding to the light beams that have passed through the different positions. Then, the parallax acquisition unit 802 may calculate the parallax by using the output image data. In addition, the photoelectric conversion system 80 includes a distance acquisition unit 803 that calculates the distance to the object in accordance with the calculated parallax, and a collision determination unit 804 that determines whether there is a possibility of collision in accordance with the calculated distance. Here, the parallax acquisition unit 802 and the distance acquisition unit 803 are examples of a distance information acquisition unit that obtains distance information to the object. That is, the distance information refers to information regarding the parallax, the defocus amount, the distance to the object, and the like. The collision determination unit 804 may determine the possibility of collision by using any of these pieces of distance information. It should be noted that the distance information may be obtained by time-of-flight (ToF). The distance information acquisition unit may be achieved by dedicatedly designed hardware or a software module. Alternatively, the distance information acquisition unit may also be achieved by a field programmable gate array (FPGA), an application-specific integrated circuit (ASIC) or a combination thereof.

The photoelectric conversion system 80 is connected to the vehicle information acquisition device 810 and can obtain vehicle information, such as a vehicle speed, a yaw rate, and a steering angle. In addition, the photoelectric conversion system 80 is connected to a control ECU 820 that is a control device for outputting a control signal that causes a vehicle to generate a braking force in accordance with determination results by the collision determination unit 804. In addition, the photoelectric conversion system 80 is also connected to an alarm device 830 that issues a warning to the driver in accordance with determination results by the collision determination unit 804. For example, when the collision determination unit 804 has determined a high possibility of collision as a determination result, the control ECU 820 performs vehicle control that avoids collision and reduces damage by applying brakes, releasing the accelerator, and suppressing engine output. The alarm device 830 warns the user by emitting an alarm such as sound, displaying alarm information on the screen of a car navigation system, or applying vibrations to the seatbelt or the steering wheel.

In the embodiment, the photoelectric conversion system 80 images the surroundings of the vehicle, such as the front or the rear of the vehicle. FIG. 8C illustrates the photoelectric conversion system 80 that images the front of the vehicle (imaging range 850). The vehicle information acquisition device 810 sends an instruction to the photoelectric conversion system 80 or the semiconductor device 800. Such a structure can further improve the accuracy of distance measurement.

An example of control that avoid collisions with other vehicles has been described above, but the photoelectric conversion system 80 is also applicable to control that performs autonomous driving while following other vehicles, control that performs autonomous driving while staying in the lane, and the like. In addition, the photoelectric conversion system 80 is applicable not only to a vehicle, such as an automobile, but also to a movable body (moving device), such as a ship, an aircraft, or an industrial robot. This movable body includes one or both of a driving force generation unit that generates a driving force mainly used to move the movable body, and a rotating body mainly used to move the movable body. The driving force generation unit can be an engine, a motor, or the like. The rotating body can be a tire, a wheel, a screw of a ship, a propeller, or the like. In addition, the photoelectric conversion system 80 is widely applicable to devices that use object recognition, such as an intelligent transport system (ITS) in addition to the movable body.

The device according to the embodiment can be a transport device, such as a vehicle, a ship, or an aircraft. The mechanical device in the transport device can be used as a moving device. The device as the transport device is suitable for a device for transporting semiconductor units or a device for assisting and/or automating operation (control) by using imaging functions. The processing device for assisting and/or automating operation (control) can perform processing for operating the mechanical device as a moving device in accordance with information obtained by the semiconductor unit.

It should be noted that the photoelectric conversion device is described as an example of the semiconductor device in the embodiment, the semiconductor device may also be another semiconductor device or both of them.

The present disclosure can improve the planarization property of the top portion of the uneven structure of the semiconductor device.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-227250, filed Dec. 24, 2024, which is hereby incorporated by reference herein in its entirety.

What is claimed is:

1. A method of manufacturing a semiconductor device including a substrate having a first surface and a second surface that faces away from the first surface and a plurality of wiring layers, the second surface being disposed between the first surface and the plurality of wiring layers, the method comprising:
preparing the substrate to have an uneven structure including a recessed portion and a raised portion that are provided on the first surface; and
forming the first film with a flat upper surface by applying a precursor onto the substrate such that an amount of the precursor applied onto the recessed portion is greater than an amount of the precursor applied onto other portions.

2. The method of manufacturing the semiconductor device according to claim 1,
wherein an upper surface of the precursor is planarized and cured to have a flat upper surface in the forming the first film.

3. The method of manufacturing the semiconductor device according to claim 1,
wherein a superstrate is brought into contact with the precursor in the forming the first film.

4. The method of manufacturing the semiconductor device according to claim 3,
wherein the precursor is cured with the superstrate in contact with the precursor in the forming the first film.

5. The method of manufacturing the semiconductor device according to claim 1,
wherein the precursor is applied such that the amount of the precursor applied onto the recessed portion is greater than an amount of the precursor applied onto a portion between a plurality of the uneven structures in the forming the first film.

6. The method of manufacturing the semiconductor device according to claim 1,
wherein the precursor is applied such that the amount of the precursor applied onto the recessed portion is greater than an amount of the precursor applied onto the raised portion in the forming the first film.

7. The method of manufacturing the semiconductor device according to claim 1,
wherein the substrate includes a plurality of photoelectric conversion units that generate electric charge that depends on light incident on the first surface,
wherein the plurality of photoelectric conversion units is separated from each other by a separating portion that extends from the first surface, and
wherein the precursor is applied such that an amount of the precursor applied onto the recessed portion is greater than an amount of the precursor applied onto the separating portion in the forming the first film.

8. The method of manufacturing the semiconductor device according to claim 1,
wherein the substrate includes a photoelectric conversion unit that generates electric charge that depends on light incident on the first surface, and
the uneven structure is disposed at a position that overlaps at least a portion of the photoelectric conversion unit in plan view of the first surface.

9. The method of manufacturing the semiconductor device according to claim 1, further comprising:
forming an insulating film on the uneven structure,
wherein the first film is formed on the insulating film in the forming the first film.

10. The method of manufacturing the semiconductor device according to claim 1, further comprising:
forming a fixed charge film on the uneven structure,
wherein the first film is formed on the fixed charge film in the forming the first film.

11. The method of manufacturing the semiconductor device according to claim 1, further comprising:
forming an anti-reflection film on the uneven structure,
wherein the first film is formed on the anti-reflection film in the forming the first film.

12. The method of manufacturing the semiconductor device according to claim 1, further comprising:
forming a fixed charge film on the uneven structure; and
forming an anti-reflection film on the fixed charge film,
wherein the first film is formed on the anti-reflection film in the forming the first film.

13. The method of manufacturing the semiconductor device according to claim 1,
wherein the substrate includes a plurality of avalanche photodiodes, each of the plurality of avalanche photodiodes including:
a first semiconductor region of a first conductivity type disposed at a first depth, and
a second semiconductor region of a second conductivity type disposed at a second depth that is deeper than the first depth with respect to the second surface.

14. The method of manufacturing the semiconductor device according to claim 13,
wherein a third semiconductor region of the second conductivity type is provided at a third depth that is deeper than the second depth with respect to the second surface.

15. The method of manufacturing the semiconductor device according to claim 14,
wherein a fourth semiconductor region of the first conductivity type is provided between the second semiconductor region and the third semiconductor region, and
impurity concentration of the first conductivity type in the fourth semiconductor region is smaller than impurity concentration of the first conductivity type in the first semiconductor region.

16. The method of manufacturing the semiconductor device according to claim 13,
wherein a fifth semiconductor region that surrounds the first semiconductor region in plan view from the first surface is provided at the first depth, and
impurity concentration in the fifth semiconductor region is smaller than impurity concentration in the first semiconductor region.

17. The method of manufacturing the semiconductor device according to claim 1,
wherein the recessed portion has a trench structure.

18. The method of manufacturing the semiconductor device according to claim 1, further comprising:
forming a microlens on the first film.

19. The method of manufacturing the semiconductor device according to claim 1, further comprising:
forming a filter layer on the first film.

20. The method of manufacturing the semiconductor device according to claim 1, further comprising
forming a filter layer on the first film; and
forming a microlens on the filter layer.
